(19) United States
(12) Patent Application Publication
(10) Pub. No.: US 2026/0363068 A1
(43) Pub. Date: Nov. 12, 2026

(54) HEAT CONDUCTIVE JOINING STRUCTURE, HEAT CONDUCTIVE JOINING METHOD, HEATSINK INCLUDING THE HEAT CONDUCTIVE JOINING STRUCTURE, AND SEMICONDUCTOR DEVICE INCLUDING THE HEAT CONDUCTIVE JOINING STRUCTURE

(71) Applicants: Lotus Thermal Solution Inc., Osaka-shi, Osaka (JP); OSAKA UNIVERSITY, Suita-shi, Osaka (JP)

(72) Inventors: Takuya IDE, Osaka-shi (JP); Masaaki MURAKAMI, Osaka-shi (JP); Tomiyuki NUMATA, Osaka-shi (JP); Hiroaki TATSUMI, Suita-shi (JP)

(73) Assignees: Lotus Thermal Solution Inc., Osaka-shi, Osaka (JP); OSAKA UNIVERSITY, Suita-shi, Osaka (JP)

(21) Appl. No.: 19/105,131

(22) PCT Filed: May 18, 2023
(86) PCT No.: PCT/JP2023/018545

§ 371 Date: Feb. 20, 2025

(30) Foreign Application Priority Data
Aug. 25, 2022 (JP) 2022-133874

(51) Int. Cl. H10W 40/20; H10W 40/00; H10W 40/22; H10W 40/25; H10W 90/00; H10W 90/10

(52) U.S. Cl. CPC H10W 40/242; H10W 40/037; H10W 40/235; H10W 40/257; H10W 90/734; H10W 40/226; H10W 90/10

(57) ABSTRACT

A heat conductive joining structure includes a joining layer that is in tight contact with a certain member to perform heat conduction with the member, and includes: a metallic porous base plate provided with a plurality of through-holes extending in a thickness direction and opening on both front and back plate surfaces of the porous base plate; and a solder solidified body including filling portions with which the through-holes of the porous base plate are filled, and solder films that are continuous with the filling portions and spread on at least one of the plate surfaces, in which the solder film is in tight contact with and joins to the facing member.

### TECHNICAL FIELD

The present invention relates to a heat conductive joining structure and a heat conductive joining method, which are suitable for a joining structure of a heat receiving body and a radiation fin in a heatsink, and a joining structure of components in a semiconductor device.

### BACKGROUND ART

In a recent semiconductor device, particularly in a power semiconductor device, the heat generation amount of a semiconductor chip increases with the increase in current density. Further, as for the semiconductor device, downsizing is expected, and it is more important to efficiently transport the heat of the semiconductor chip having a large heat generation amount, to a heatsink that is a cooler, and to radiate the heat from the heatsink to a gas-phase or liquid-phase cooling medium. In a typical semiconductor device, for example, a circuit substrate and a semiconductor chip are laminated on a base plate, and the heatsink is attached below a bottom surface of the base plate. Between the members that are laminated, a heat conductive sheet that maintains a suitable heat conduction and that joins the members is provided (see Patent Literature (PTL) 1, for example).

By the way, the semiconductor device has a structure in which a plurality of members (a semiconductor chip, a circuit substrate, a base plate, and the like) respectively having different linear expansion coefficients are joined to each other and are laminated. Therefore, a large temperature change due to the above heat generation causes heat strain to occur in parts of the semiconductor device, and particularly causes breakage and peeling of the heat conductive sheet that is a joining portion. For preventing the breakage of the joining portion due to the heat strain, it is possible that a solder layer that has low stiffness and that can mitigate stress is adopted instead of the heat conductive sheet. However, solders have a relatively high heat resistance, declining the heat radiation through the heat conduction between members. Further, the stiffness cannot be kept in the lamination direction of the members, i.e., in the plate thickness direction orthogonal to the joining surfaces, thereby causing the durability of the device to be limited. Furthermore, it is difficult to keep the parallelism between members at the time of joining assembly, causing a problem in assembly accuracy.

### CITATION LIST

### Patent Literature

PTL 1: Japanese Unexamined Patent Application Publication No. Hei. 11-58591

### SUMMARY OF INVENTION

### Technical Problem

In view of the above-described circumstances, a purpose of the present invention is to provide a heat conductive joining technique: that is suitable for the joining structure of a semiconductor device; that can mitigate the stress due to heat strain; that can prevent the breakage and peeling of a joining portion; that has a low heat resistance; that can enhance the heat radiation by heat conduction between members; and that makes it possible to expect downsizing and long life, and furthermore a heat conduction joining technique: that can keep the stiffness in the lamination direction of members; that can keep the durability and the parallelism between members at the time of joining assembly; and that can also enhance the assembly accuracy.

### Solution to Problem

In view of the present state, the inventors has diligently worked and found a solder and a metal plate that has a plurality of through-holes extending in the thickness direction are combined, thereby achieving a joining structure: that mitigates the stress in a horizontal direction parallel to the surface; that can prevent the breakage and the peeling; that reduces the heat resistance in the thickness direction (plate thickness direction); that has excellent heat conductibility; that can keep the stiffness in the thickness direction; and also that makes it possible to obtain the assembly accuracy. The inventors also found that the heat conductive joining structure is effective for devices other than the semiconductor device, and such a heat conductive joining structure can be applied to a joining structure between a heat receiving body and a radiation fin of a novel heatsink. Thus, the present inventors have completed the present invention.

Further, as a result of examination for changes in heat conductivity in the thickness direction and apparent stiffness in an in-plane direction when the volume ratio between a metal plate (copper plate) and solder was changed under an experiment condition described below, a graph in FIG. 11 was obtained. From the graph, the larger the volume (the volume of a thickness portion except holes) of the metal plate is (as the void ratio is smaller), the greater the heat conductivity is, but the apparent stiffness in the in-plane direction increases at an accelerated pace. This reveals that the volume of the metal plate is preferably set in a range of 70 vol % or less (the void ratio is in a range of 30 vol % or more), and more preferably in a range of 20 vol % or more and 70 vol % or less (the void ratio is in a range of 30 vol % or more and 80 vol % or less), for satisfying both the heat conductibility and the mitigation of the stress.

### (Experiment Condition)

Plate thickness of joining layer: 200 μm
Solder: SAC305 (Sn−3 mass % Ag−0.5 mass % Cu)
Heat conductivity measurement device: TCM1001 (manufactured by RHESCA CO., LTD.)

The present invention includes the following inventions.
(1) A heat conductive joining structure including a joining layer that is in tight contact with a certain member to perform heat conduction with the member, the joining layer including: a metallic porous base plate provided with a plurality of through-holes extending in a thickness direction and opening on both front and back plate surfaces of the porous base plate; and a solder solidified body including filling portions with which the through-holes of the porous base plate are filled, and a solder film that is continuous with the filling portions and spreads on at least one of the plate surfaces, in which the solder film is in tight contact with and joins to the member which the solder film faces.
(2) A heat conductive joining structure including a joining layer that is provided between two members to join the two members, and transfers heat from one of the two members to a remaining one of the two members, the joining layer including: a metallic porous base plate that is provided with a plurality of through-holes and is interposed between the two members, the plurality of through-holes extending in a thickness direction and opening on both front and back plate surfaces of the metallic porous base plate; and a solder solidified body including filling portions with which the through-holes of the porous base plate are filled, and a solder film that is continuous with the filling portions and spreads on each of the plate surfaces, in which the solder film is in tight contact with and joins to a corresponding one in the two members which the solder film faces.
(3) The heat conductive joining structure according to (1) or (2), in which a void ratio due to the through-holes of the porous base plate constituting the joining layer is 30 to 80 vol %.
(4) A heat conductive joining method including providing a joining layer that is in tight contact with a certain member to perform heat conduction with the member, the providing the joining layer including: providing a metallic porous base plate provided with a plurality of through-holes extending in a thickness direction and opening on both front and back plate surfaces of the metallic porous base plate; and filling the through-holes of the porous base plate with a solder material, forming a solder film that is continuous with filling portions and spreads on at least one of plate surfaces of the porous base plate, and performing solidification, thereby providing a solder solidified body in which the solder film is in tight contact with and joins to the member which the solder film faces.
(5) A heat conductive joining method including providing a joining layer between two members to join the two members, the joining layer transferring heat from one of the two members to a remaining one of the two members, the providing the joining layer including: interposing a metallic porous base plate provided with a plurality of through-holes between the two members, the plurality of through-holes extending in a thickness direction and opening on both front and back plate surfaces of the metallic porous base plate; and filling the through-holes of the porous base plate with a solder material, forming a solder film that is continuous with the filling portions and spreads on each of the plate surfaces, and performing solidification, thereby providing a solder solidified body, in which the solder film is in tight contact with and joins to a corresponding one of the two members, which the solder film faces.
(6) The heat conductive joining method according to (4) or (5), including: interposing the solder material between one or both of the front and back plate surfaces of the porous base plate and the member that faces at least one of the front and back plate surfaces; and stacking and heating the member, the porous base plate, and the solder material, melting the solder material, filling the through-holes of the porous base plate with the solder material, forming a solder film that is continuous with the filling portions and spreads on each of the plate surfaces, and performing cooling solidification, thereby forming the solder solidified body.
(7) The heat conductive joining method according to (6), in which the two members, the porous base plate, and the solder material are stacked in a vertical direction, and are heated to melt the solder material while the solder material is disposed on a top surface of the porous base plate; the solder material falls and fills into the through-holes due to a self-weight of the solder material and a weight of a member above the solder material; the solder material leaks from openings of the through-holes on a lower side thereof, spreads on a gap between the porous base plate and a member below the porous base plate, and forms the solder film on the plate surface of the porous base plate on a lower side; and a residual solder material that has not fallen into the through-holes forms the solder film on the plate surface of the porous base plate on an upper side.
(8) A heatsink including the heat conductive joining structure according to (1), the heatsink including: a metallic heat absorber as the certain member, the heat absorber having an abutting surface that abuts on an object to be cooled, and transfer heat of the object to the heat absorber through the abutting surface; and a metallic plate-shaped fin as the porous base plate, the metallic plate-shaped fin having a plate surface with a partial region that joins to a surface of the heat absorber on an opposite side of the abutting surface, in which the plate-shaped fin is provided with a plurality of through-holes opened on the plate surface; the solder solidified body is provided at the partial region of the plate-shaped fin, the solder solidified body including the filling portions with which through-holes formed at the partial region are filled, and the solder film that is continuous with the filling portions and spreads on the plate surface, and the solder film is in tight contact with the heat absorber which the solder film faces to form the joining layer that performs heat conduction with the heat absorber; and heat is radiated to an exterior through through-holes at a residual region of the plate-shaped fin, the residual region of the plate-shaped fin projecting at a periphery of the heat absorber.
(9) A heatsink including the heat conductive joining structure according to (2), the heatsink including: a metallic heat absorber as one member of the two members, the heat absorber having an abutting surface that abuts on an object to be cooled, and transfers heat of the object to be cooled to the heat absorber through the abutting surface; a first metallic plate-shaped fin as the porous base plate, the first metallic plate-shaped fin having a plate surface with a partial region that joins to a surface of the heat absorber on an opposite side of the abutting surface; a metallic coupling body as a remaining one of the two members, the metallic coupling body joining to a region of a plate surface of the first plate-shaped fin on an opposite side of the plate surface with the partial region, the region corresponding to the partial region; and a second metallic plate-shaped fin having a plate surface with a partial region that joins to a surface of the coupling body on an opposite side of the surface joining to the first plate-shaped fin, in which each of the first plate-shaped fin and the second plate-shaped fin has a plate surface on which a plurality of through-holes open; the solder solidified body is provided at the partial region of the first plate-shaped fin, the solder solidified body including the filling portions with which through-holes formed at the partial region are filled, and the solder film that is continuous with the filling portions and spreads on plate surface of the first plate-shaped fin, the solder film being in tight contact with the heat absorber which the solder film faces and the coupling body which the solder film faces, the joining layer is formed, the joining layer transferring heat from the heat absorber to the coupling body; and heat is radiated to an exterior through through-holes at a residual region of the first plate-shaped fin and through-holes at a residual region of the second plate-shaped fin, the residual region of the first plate-shaped fin projecting at a periphery of the heat absorber and the coupling body, the residual region of the second plate-shaped fin projecting at a periphery of the coupling body.
(10) A semiconductor device including: a base plate; a circuit substrate that joins on the base plate; and a semiconductor chip that is joined on the circuit substrate, in which the heat conductive joining structure according to (2) including the joining layer is included in at least one of an interval between two members including the base plate and the circuit substrate and an interval between two members including the circuit substrate and the semiconductor chip.
(11) A semiconductor device including: a heatsink provided below a bottom surface of a base plate on which a circuit substrate and a semiconductor chip are laminated, and the heat conductive joining structure according to (2) including the joining layer between two members including the base plate and the heatsink.

### Advantageous Effects of Invention

With the heat conductive joining structure/heat conductive joining method in the present invention, the metallic porous base plate in which the through-holes are filled with solder easily expands and contracts in the horizontal direction parallel to the joining surfaces, and can mitigate the stress, and the filling portions that are continuous with the solder film exerts an anchor effect, and therefore, can prevent the breakage and the peeling.

That is, the porous base plate having the plurality of through-holes in the plate thickness direction deforms in the horizontal direction, and can mitigate the stress. Further, the filling portion of the solder with which each through-hole is filled has a rod shape in the plate thickness direction, and therefore, easily bends in the horizontal direction, to further promote the mitigation of the stress in the horizontal direction. The filling portion that is continuous with the solder film and with which each through-hole is filled, as an anchor, maintains a strong integration property and tight contact property between the solder film and the porous base plate.

Further, the solder film that tightly contacts the member is included. The periphery of the through-hole that is filled with the solder is a metal plate material, and therefore, has a low heat resistance along the plate thickness (thickness) direction, and an excellent tight contact property and heat conductibility for the member. Since the through-hole is filled with the solder, the increase in heat resistance due to existence of a void can be avoided, there is a wide contact area including the filling portions with which the through-holes are filled, between the solder solidified body and the porous base plate, and the heat received by the solder film can be efficiently transferred to the porous base plate.

Furthermore, each through-hole of the porous base plate extends in the thickness direction, and therefore, excellent stiffness is kept in the plate thickness direction orthogonal to the joining surfaces. Further, the filling portion of the solder with which each through-hole is filled has a rod shape that extends in the plate thickness direction as described above, and therefore, further improves the stiffness in the plate thickness direction that is an axial center direction. Accordingly, the accuracy at the time of the assembly is easily obtained. That is, a joining structure having a low heat resistance and excellent heat conductibility can be realized at an accuracy for a thickness, a parallelism, and the like in accordance with the design.

It is preferable that the void ratio due to the though-holes of the porous base plate constituting the joining layer be 30 to 80 vol %. When the above void ratio is less than 30%, the stress mitigation effect easily becomes low. Further, in the case of being more than 80%, the vertical stiffness becomes low, the whole easily deforms, and the accuracy of the joining portion about the thickness and the like easily becomes incapable of being maintained.

Further, with the method for forming the solder solidified body by interposing the solder material between one or both of the front and back plate surfaces of the porous base plate and the member that faces one or both of the front and back plate surfaces, stacking and heating the member, the porous base plate, and the solder material, melting the solder material, filling the through-holes of the porous base plate with the solder material, forming solder films that are continuous with the filling portions and that spread on both plate surfaces, and performing cooling solidification, an accurate heat conductive joining structure according to the present invention can be efficiently realized.

In the case of the providing between two members, by the method in which the two members, the porous base plate, and the solder material are stacked in the vertical direction such that the solder material is disposed on the upper surface side of the porous base plate, and are heated, the solder material is molten, the solder material falls into the through-holes due to the self-weight of the solder material and the load from the member on the upper side, the filling is performed, the solder material leaks from the openings of the through-holes on the lower side, spreads on the gap between the porous base plate and the member on the lower side, and the solder film is formed on the plate surface on the lower side, and the residual solder material that has not fallen into the through-holes forms the solder film on the plate surface on the upper side, an accurate heat conductive joining structure according to the present invention can be efficiently realized.

Further, with the above heatsink including the heat conductive joining structure according to the present invention, it is possible to have an excellent tight contact property and heat conductibility in the joining portion between the heat absorber and the plate-shaped fin, to have excellent heat radiation, to mitigate the stress that is generated in the joining portion, and to prevent the peeling. Further, it is possible to stably and efficiently provide an excellent-quality heatsink that has high stiffness and assembly accuracy and that has strength and accuracy in accordance with the design. Further, by the heat conductive joining structure according to the present invention, similarly, it is possible to stably and efficiently provide a high-quality heatsink in which the coupling body and the second plate-shaped fin are further joined and that has a better heat radiation.

Further, with the above semiconductor device including the heat conductive joining structure according to the present invention, it is possible to have an excellent tight contact property and heat conductibility in the joining portion between the base plate and the circuit substrate or between the circuit substrate and the semiconductor chip, to mitigate the stress that is generated in the joining portion, and to prevent the break and the peeling. Consequently, it is possible to achieve efficient heat radiation and stress mitigation, and to expect the downsizing and long life of the semiconductor device. Further, it is possible to stably and efficiently provide an excellent-quality semiconductor device that has high stiffness and assembly accuracy and that has strength and accuracy in accordance with the design.

Further, in the semiconductor device in which the heatsink is provided on the lower surface side of the base plate on which the circuit substrate and the semiconductor chip are laminated and the joining layer is included between the two members of the base plate and the heatsink, it is possible to have an excellent tight contact property and heat conductibility in the joining portion between the base plate and the heatsink, to have excellent heat radiation, to mitigate the stress that is generated in the joining portion, and to prevent the peeling of the heatsink. Further, it is possible to stably and efficiently provide an excellent-quality semiconductor device that has high stiffness and assembly accuracy and that has strength and accuracy in accordance with the design.

### BRIEF DESCRIPTION OF DRAWINGS

FIG. 1A is a perspective view showing the concept of a heat conductive joining structure in the present invention.

FIG. 1B is a cross-sectional view showing the concept of the heat conductive joining structure.

FIG. 2 is an explanatory diagram showing a heat conductive joining method in the present invention.

FIG. 3 is an explanatory diagram showing a modification of the heat conductive joining structure

FIG. 4A is a perspective view showing the concept of the heat conductive joining structure in the present invention, which is provided between two members.

FIG. 4B is a cross-sectional view showing the concept of the heat conductive joining structure.

FIG. 5 is an explanatory diagram showing the heat conductive joining method in the present invention for joining two members.

FIG. 6A is a perspective view showing an example of a heatsink including the heat conductive joining structure in the present invention.

FIG. 6B is a sectional view showing the example of the heatsink.

FIG. 7 is an explanatory diagram showing steps in the production of the heatsink.

FIG. 8A is a perspective view showing an example of the heatsink including the heat conductive joining structure in the present invention, which is provided between two members.

FIG. 8B is a cross-sectional view of the example of the heatsink.

FIG. 9 is an explanatory diagram showing steps in the production of the heatsink.

FIG. 10 is a cross-sectional view showing an example of a semiconductor device including the heat conductive joining structure in the present invention, which is provided between two members.

FIG. 11 is a graph showing changes in heat conductivity in a thickness direction and apparent stiffness in an in-plane direction.

### DESCRIPTION OF EMBODIMENTS

Next, embodiments of the present invention will be described in detail based on the accompanying drawings.

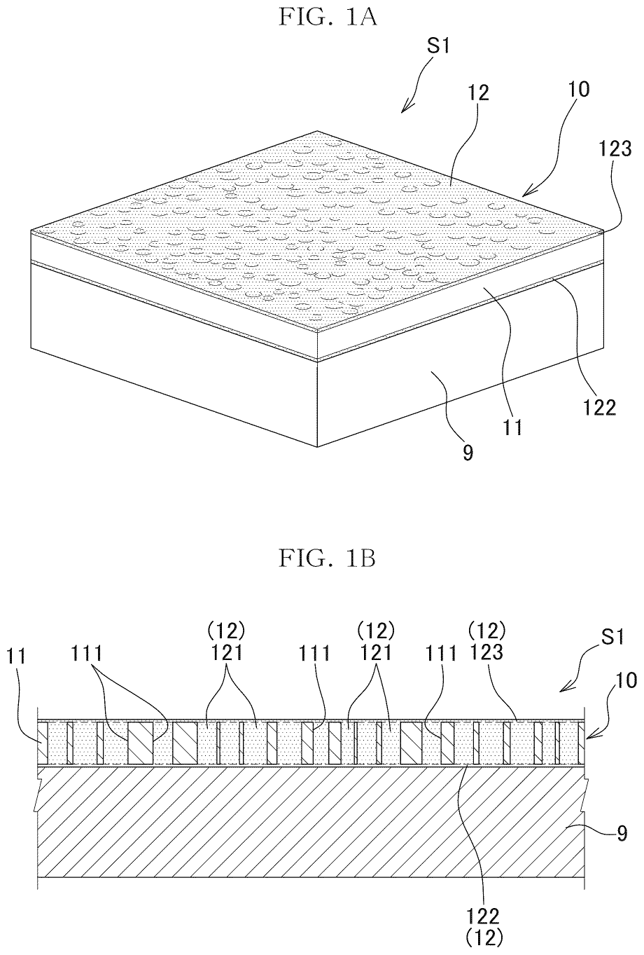

First, a heat conductive joining structure and a heat conductive joining method in the present invention will be described based on FIG. 1A to FIG. 5. As shown in FIG. 1A and FIG. 1B, a heat conductive joining structure S1 according to the present invention includes a joining layer 10 that is in tight contact with a certain member 9 and performs heat conduction with the member 9.

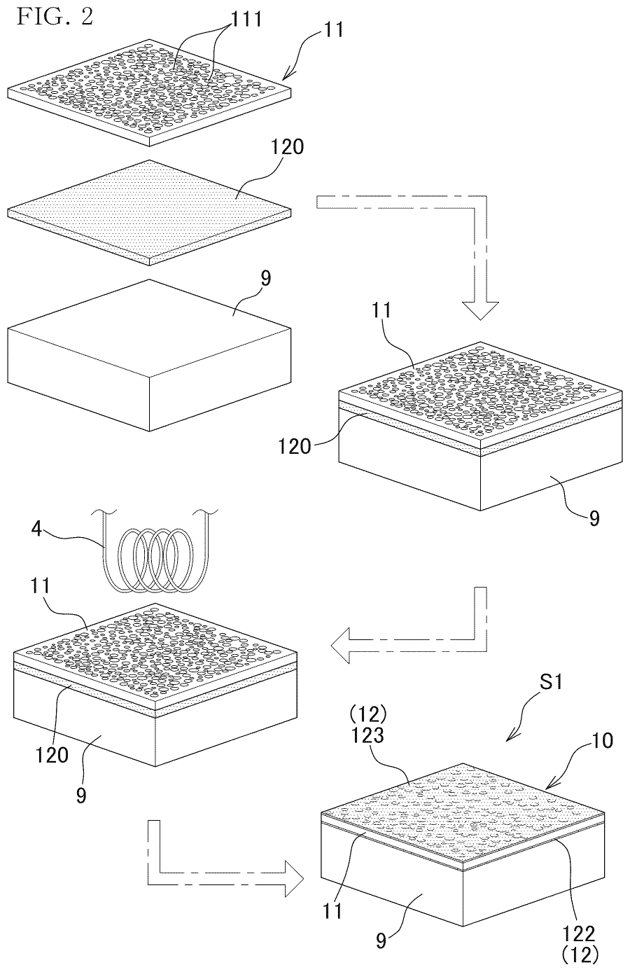

As shown in FIG. 1A, FIG. 1B, and FIG. 2, the joining layer 10 includes a metallic porous base plate 11 provided with a plurality of through-holes 111 that extend in a thickness direction and open on both front and back plate surfaces, and a solder solidified body 12 including filling portions 121 with which the through-holes 111 of the porous base plate 11 are filled and solder films 122 and 123 that are continuous with the filling portions and spread on at least one plate surface. Moreover, the solder film 122 is in tight contact with and is joined to the facing member 9.

In this heat conductive joining structure S1 in the present invention, the porous base plate 11 is made of metal, and thus has a low heat resistance, thereby having an excellent tight contact property and heat conductibility for the member 9. In addition, the porous base plate 11 includes the through-holes 111 extending in the thickness direction, and thus easily deforms in a horizontal direction so as to mitigate the stress. Further, the filling portion 121 that is continuous with the solder film 122 and fills in each through-hole 111 maintains a strong integration property and tight contact property between the solder film 122 and the porous base plate 11, as an anchor.

Further, the heat conductive joining structure S1 includes the solder film that is in tight contact with the member. The periphery of each through-hole that is filled with the solder is a metal plate material, and therefore has a low heat resistance along the plate thickness direction, thereby having an excellent tight contact property and heat conductibility for a member. A wide contact area is secured between the solder solidified body 12 and the porous base plate 11 by the filling portions 121 with which the through-holes 111 are filled, to thereby efficiently transfer the heat received by the solder film 122 to the porous base plate 11. Further, each through-hole 111 extends in the thickness direction, and therefore, the porous base plate 11 keeps excellent stiffness in the thickness direction. Furtthermore, the filling portion 121 of the solder with which each through-hole 111 is filled has a rod shape that extends in the plate thickness direction as described above, and therefore further improves the stiffness in the plate thickness direction that is the axial direction of the filling portion 121. Accordingly, the accuracy at the time of assembly is easily obtained. Specifically, a joining structure having a low heat resistance and excellent heat conductibility can be realized with an accuracy for a thickness, a parallelism, and the like in accordance with the design.

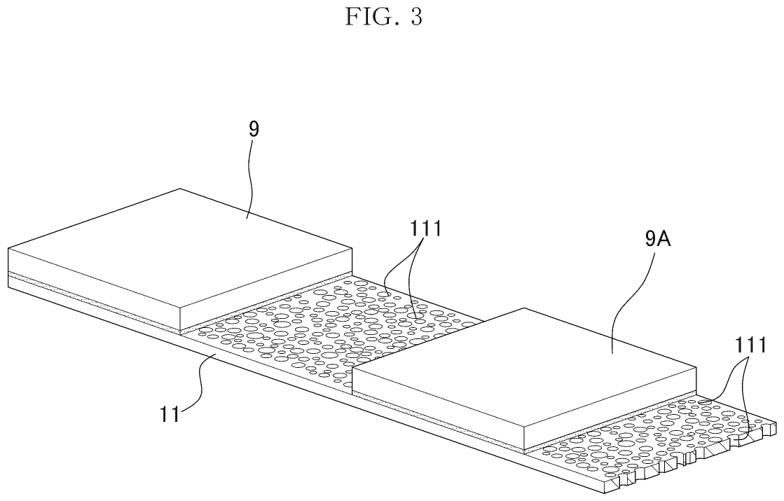

In this example, to the joining layer 10 on the opposite side of the member 9, another member may be joined, or may not be joined. The joining layer 10 has wide applicability. For example, as shown in an example of a later-described heatsink, the porous base plate 11 constituting the joining layer 10 may include, in addition to a region constituting the joining layer 10, a residual region that extends outward from the region and has another function other than joining (in the case of the later-described heatsink, a function as a cooling fin through which fluid for cooling flows). Alternatively, the porous base plate 11 may have a second joining region across a non-joining region, as shown in FIG. 3.

For the porous base plate 11, metal materials having excellent heat conductibility, as exemplified by aluminum, iron, and copper, and an alloy of such metal materials can be widely used. In the case of copper or the like, a porous plate is preferably used, which is obtained by cutting a lotus-type porous metal formed body that is formed by a metal solidification method and has a plurality of pores extending in one direction, in a direction orthogonal to the direction in which the pores extend. Here, the porous base plate in the present invention includes a porous base plate in which through-holes are provided by a drill, a laser, or the like. The lotus-type porous metal formed body can be formed by a known method such as a pressurized gas method (for example, a method disclosed in Japanese Patent No. 4235813) and a thermal decomposition method. The through-holes of the porous plate cut out from the lotus-type porous metal formed body in this way are pores cut by the cutting process.

In addition to the through-holes, there are bottomed holes that do not penetrate (a hole obtained by cutting a pore at a position that does not communicate with the pore). Such bottomed holes have an effect of increasing the contact area with the solder solidified body 12. The later-described heatsink has an effect of increasing the surface area and promoting the heat radiation from the plate surface. The porous plate cut out from the lotus-type porous metal formed body is used in this way, thereby easily obtaining the porous base plate 11 at low cost. It is preferable that the porosity due to the through-holes 111 of the porous base plate 11, i.e., the ratio of the total volume of the interiors of the through-holes 111 to a volume of the porous base plate 11 without the holes be 20 to 70 vol %. Further, it is preferable that the opening size (diameter) of the through-hole 111 be 0.01 to 1.00 mm.

The solder (solder alloy) of the solder solidified body 12 may be appropriately selected from known solders, depending on usage environment including, for example, a temperature of the heat that is exchanged with a member to be joined and an estimated stress, the material of the porous base plate 11, the size of the through-hole, and properties, such as a wettability obtained based on the plate thickness and the like. Particularly, a Sn—Ag-based, a Sn—Cu-based, a Sn—Bi-based, a Sn—In-based solder alloy, or a solder alloy containing them as basic elements and also containing a third element is preferable.

The filling portion 121 is solidified solder that fills in the through-holes 111 of the porous base plate 11, and is integrated with the solder films 122 and 123. As described later, a solder plate stacked and disposed on the porous base plate 11 is melted to flow into the through-holes 111 by itself, and is solidified. Therefore, it is preferable to apply/deposit a coating agent such as flux and a metal film, to the surface (including an inner wall of each through-hole) of the porous base plate 11, for enhancing the wettability of the solder.

Each of the solder films 122 and 123 is a film of solder, which is continuous with the above filling portions 121, spreads on at least one plate surface, and enhances the tight contact property and adherence with the member to be joined. In this example, in addition to the solder film 122 on a side that is joined to the member 9, the solder film 123 is formed on a surface on the opposite side, but the solder film 123 can be omitted. The solder film 122 and the member 9 are in tight contact with each other strongly to conduct the heat. Unlike conventional solder joining, the solder film 122 is relatively thin, and the solder film 122 does not cause the whole stiffness and accuracy to decrease. Further, the above filling portion 121 formed so as to be continuous with the solder film 122 functions as an anchor, thereby preventing the solder film 122 from peeling off from the porous base plate 11.

FIG. 2 shows steps for forming the heat conductive joining structure S1 in this example, i.e., a heat conductive joining method including providing the joining layer 10 that is in tight contact with the member 9 to perform heat conduction with the member. First, a solder plate 120 and a porous base plate 11 are stacked on the member 9. Then, the solder plate 120 is melted by heating in a heating furnace or the like. Thereby, solder in the solder plate 120 rises through the through-holes 111 of the porous base plate 11, distills to a top surface of the porous base plate 11 to form the solder film 123, and then is solidified.

Solder that does not enter the through-holes 111 and thus remains forms the solder film 122 between the porous base plate 11 and the member 9, and is solidified. Further, solder solidified in the through-holes 111 forms the above filling portions 121. In this way, the joining layer 10 (heat conductive joining structure S1) that is in tight contact with and is joined to the member 9 is formed. The peeling between the solder film 122 and the porous base plate 11 can be prevented by the anchor effect of the filling portions 121. In this example, the solder film 123 that couples and integrates the filling portions 121 is formed at ends of the filling portions 121, thereby further enhancing the anchor effect.

In this example, the solder plate 120 is provided between the member 9 and the porous base plate 11, and is heated. It is also preferable that a solder plate be further disposed also on the top surface of the porous base plate 11, i.e., on the side where the solder film 123 is formed, and then be heated. Thus, the solder film 123 can be formed more reliably. Further, it is preferable that the through-holes 111 be filled with solder powders, in addition to the solder plate 120.

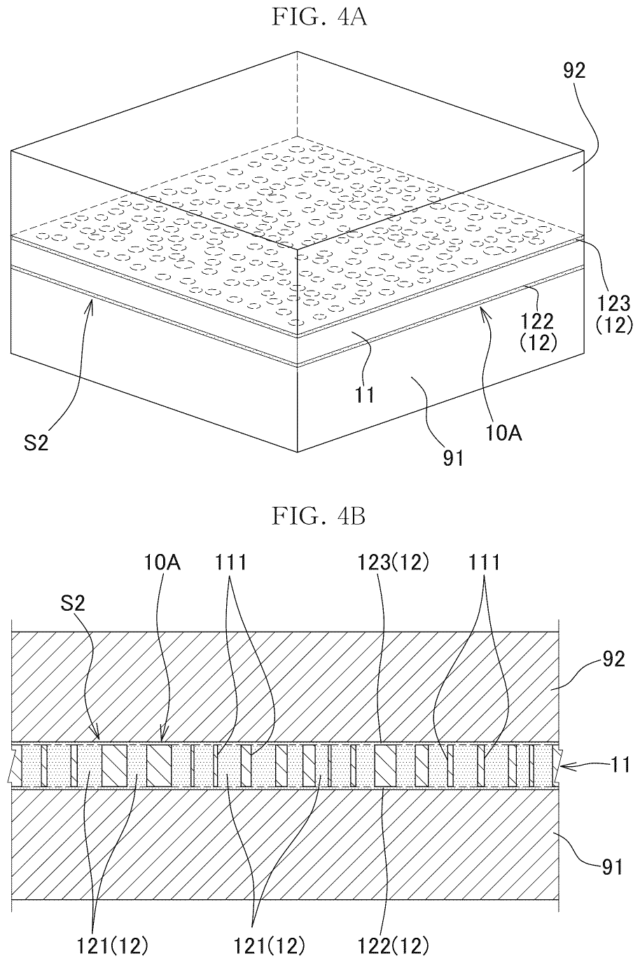

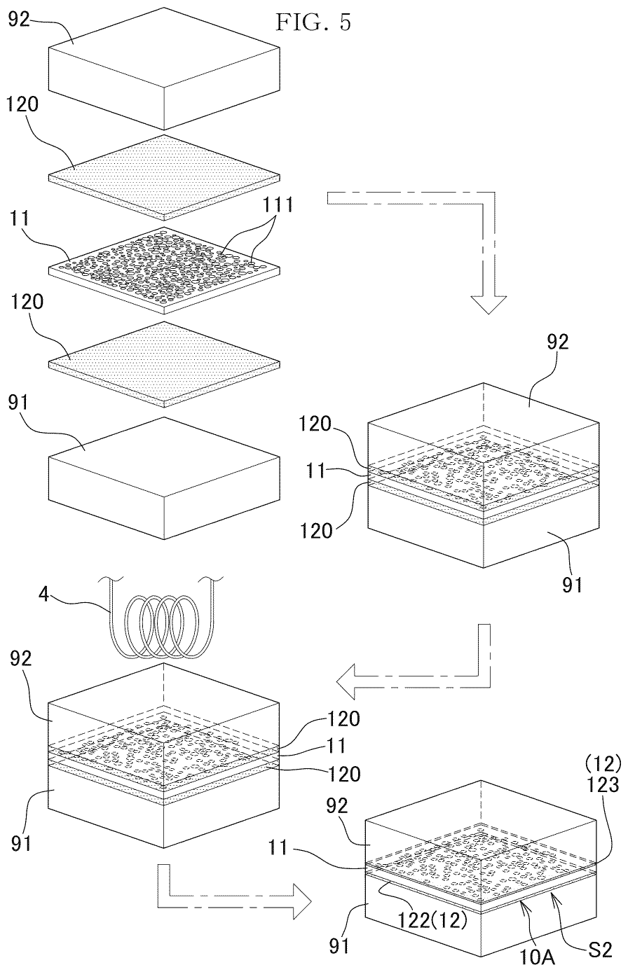

Next, an example of a heat conductive joining structure S2 including a joining layer that is provided between two members to join the members, and transfers heat from one of the two members to the other will be described based on FIG. 4A, FIG. 4B, and FIG. 5.

As shown in FIG. 4A and FIG. 4B, a joining layer 10A of the heat conductive joining structure S2 includes the above-described porous base plate 11 that is interposed between two members 91 and 92, and a solder solidified body 12 including filling portions 121 with which the through-holes 111 of the porous base plate 11 are filled, and solder films 122 and 123 that are continuous with the filling portions 121 and spread on both plate surfaces of the porous base plate 11. In the joining layer 10A, the solder films 122 and 123 are respectively in tight contact with and join the two members 91 and 92 which the solder films 122 and 123 face respectively. This heat conductive joining structure S2 in the present invention has an excellent tight contact property and heat conductibility for the members 91 and 92, in similar to the joining structure S1. In addition, the heat conductive joining structure S2 easily deforms in the horizontal direction because of a plate material including the through-holes 111 that extend in the thickness direction, to thereby mitigate the stress. Particularly, in the joining of two members, the stress is easily generated in the joining portion due to the difference in heat shrinkage between the two members, and the like. According to the present invention, such stress can be absorbed, thereby preventing break or damage before it happens.

Between the solder films 122, 123 and the porous base plate 11, a strong integration property and tight contact property are maintained while the filling portions 121 and both solder films serve as anchors. Further, in similar to the joining structure S1, a joining structure having a low heat resistance and excellent heat conductibility can be realized with an accuracy in a thickness, a parallelism, and the like in accordance with the design. The material of the porous base plate 11, the configuration of the through-holes 111 as exemplified by the porosity and the opening size, the material of the solder, and others can be regarded as being the same as those in the above structure S1, and thus descriptions thereof are omitted.

FIG. 5 shows steps for forming the heat conductive joining structure S2 in this example, i.e., a heat conductive joining method that includes providing the joining layer 10 that transfers heat from one of the two members 91 and 92 to the other, between the two members 91, 92. First, a solder plate 120, the porous base plate 11, and a solder plate 120 are stacked on one member 91 in order, and furthermore the other member 92 is stacked thereon. Then, both solder plates 120 are heated and melted by a heater 4, by being put in a heating furnace, or by other means. Thus, the through-holes 111 of the porous base plate 11 are filled with solder in the solder plates 120 from upper and lower sides, and the solder films 122 and 123 that are continuous with the filling portions 121 and spread on the both plate surfaces of the porous base plate 11 are formed.

When the solder plate 120 melts and flows into the through-holes 111, an amount of solder that flows into the holes 111 is greater on the upper side of the through-holes 11 due to gravity. Therefore, for making the thicknesses of the solder films 122 and 123 approximately the same, it is preferable that the solder plate 120 on the upper side is thicker and is provided with more solder. In this example, the solder plates 120 are disposed on both upper and lower sides of the porous base plate 11. However, for example, the solder plate may be disposed only on the upper side, and the solder plate may be omitted on the lower side. Even when the solder plate on the lower side is omitted, solder that flows downward out of the through-holes 111 spreads, and can form the solder film 122 on the lower side.

Other constitutions and modifications are the same as those in the above-described structure in FIG. 1A to FIG. 3, and descriptions thereof are omitted.

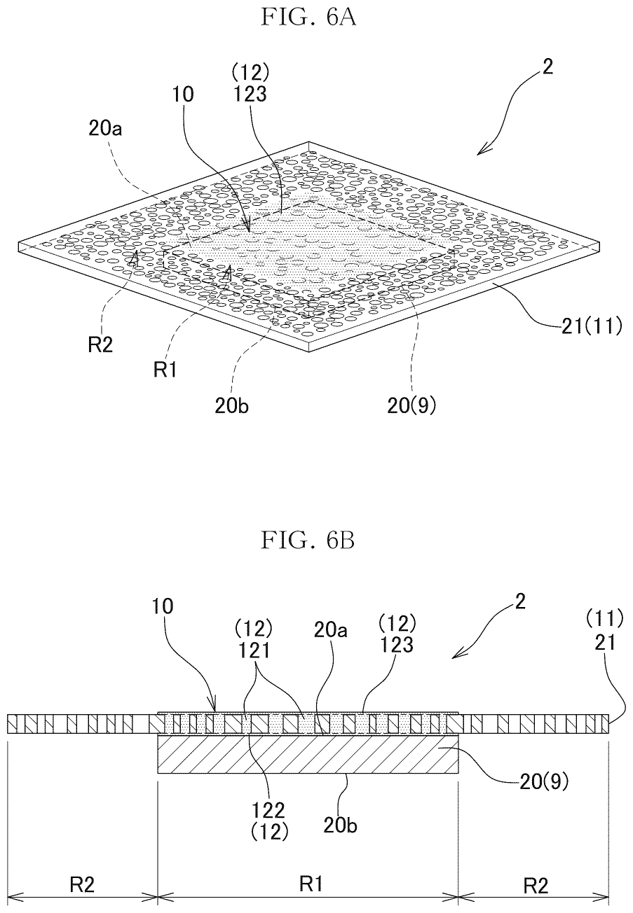

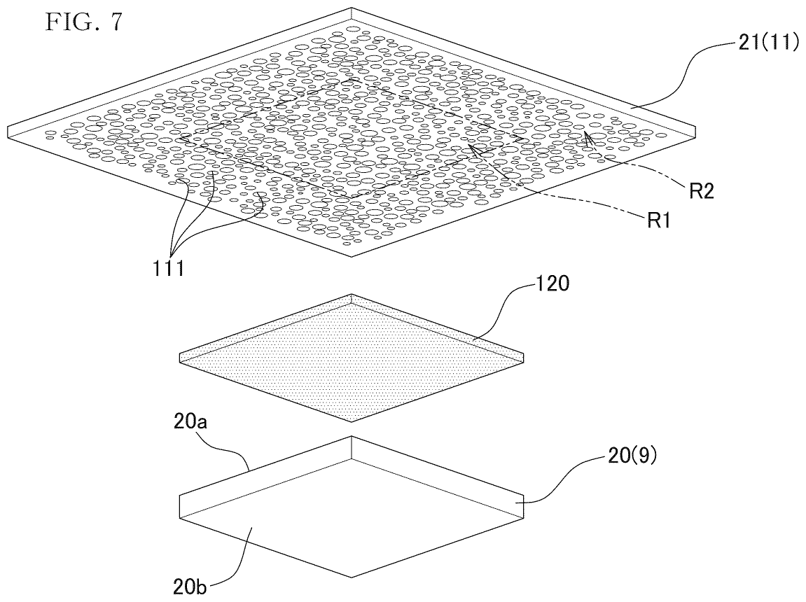

Next, an example of a heatsink constituted by the heat conductive joining structure S1 will be described based on FIG. 6A, FIG. 6B, and FIG. 7.

A heatsink 2 in this example corresponds to an improvement of a heatsink described in Japanese Unexamined Patent Application Publication No. 2018-73869. The heat conductive joining structure S1 is used, so that production can be performed more efficiently and accurately, and excellent joining strength and heat conduction from a heat absorber to a cooling fin can be obtained. Specifically, as shown in FIG. 6A and FIG. 6B, the heatsink 2 includes a metallic heat absorber 20 that has an abutting surface 20b abutting on an object to be cooled, such as a CPU, and receives the heat from the object to be cooled through the abutting surface, and a metallic plate-shaped fin 21 that has a plate surface with a partial region R1 joining to a surface 20a of the heat absorber 20 on the opposite side of the abutting surface 20b. The plate-shaped fin 21 has front and back plate surfaces provided with a plurality of through-holes 111 opening on the plate surfaces.

Moreover, at the partial region R1 of the plate-shaped fin 21, the heat absorber 20 and a joining layer 10 of the plate-shaped fin 21 are configured by the solder solidified body 12 including the filling portions 121 with which through-holes 111 at the regions R1 are filled and the solder films 122 and 123 that are continuous with the filling portions 121 and spread on the plate surfaces of the porous base plate 11, while the heat absorber 20 is adopted as the member 9 and the plate-shaped fin 21 is adopted as the porous base plate 11. The solder film 122 is in tight contact with the heat absorber 20 facing the solder film 122, and efficiently performs heat conduction with the heat absorber 20.

A residual region R2 of the plate-shaped fin 21 that projects at the periphery of the heat absorber 20 functions as a radiation fin that radiates heat to fluid that passes through the through-holes 111. The heatsink 2 in this example exerts the above-described effects obtained by the heat conductive joining structure S1, i.e., an excellent tight contact property and heat conductibility, can mitigate the stress, and has excellent joining strength, as compared to a heatsink in which a plate end portion of the radiation fin is joined to a heat absorber sidewall as in the conventional heatsink.

Further, the filling portion 121 that is continuous with the solder film 122 and fills in each through-hole 111 maintains a strong integration property and tight contact property between the solder film 122 and the plate-shaped fin 21, as an anchor. Further, a joining structure having a low heat resistance and excellent heat conductibility can be easily realized with an accuracy in thickness, parallelism, and the like in accordance with the design. In this example, the solder film 123 is formed also on the surface of the plate-shaped fin 21 on the opposite side of the heat absorber 20, but this film can be omitted.

For the heatsink 2, as shown in FIG. 7, on an upper surface of the heat absorber 20, the solder plate 120 having a shape same as that of the heat absorber 20 in planar view is placed, and furthermore the plate-shaped fin 21 is stacked over the solder plate 120. The plate-shaped fin 21 is placed so that the region R1 at the center is put on the solder plate 120 and the residual region R2 is positioned at the periphery of the region R1. Then, the solder plate 120 is heated and molten by the heater 4, by being put in a heating furnace, or by other means. Thus, solder in the solder plate 120 rises through the through-holes 111 at the region R1 on the center side of the plate-shaped fin 21, distills to a top surface of the plate-shaped fin 21, forms the solder film 123, and is solidified.

Solder that does not enter the through-holes 111 and remains forms the solder film 122 between the plate-shaped fin 21 and the heat absorber 20, and is solidified. Further, solder solidified in the through-holes 111 forms the filling portions 121. In this way, the joining layer 10 (heat conductive joining structure S1) that is in tight contact with and joins to the heat absorber 20 is formed.

The heat absorber 20 is made of metal and has a solid cubic shape, but is not limited to this configuration at all. A hollow shape may be adopted instead of the solid shape. Materials that are used in conventional heatsinks, as exemplified by aluminum, iron, and copper, can be widely applied. Further, a heat pipe may be incorporated in the heat absorber 20, or a heat pipe itself may configure the heat absorber 20.

As the metal material used for the plate-shaped fin 21, materials that are used in plate-shaped fins of conventional heatsinks, as exemplified by aluminum, iron, and copper, can be widely applied, similarly to the heat absorber 20. In this example, the plate-shaped fin 21 is made of copper, and is specifically prepared by cutting a lotus-type porous metal formed body that is formed by the metal solidification method and has a plurality of pores extending in one direction, in a direction orthogonal to the direction in which the pores extend. In the plate material cut out from the lotus-type porous metal formed body, there are bottomed holes that do not penetrate, other than the through-holes 111. Such bottomed holes have an effect of increasing the surface area of the plate surface at the region R2 for the function as the radiation fin, and have an effect of promoting the heat radiation from the plate surface. The shape of the plate-shaped fin 21 is a square shape, but is not limited thereto at all. A shape other than the square shape, as exemplified by a polygonal shape and a circular shape, can be naturally adopted.

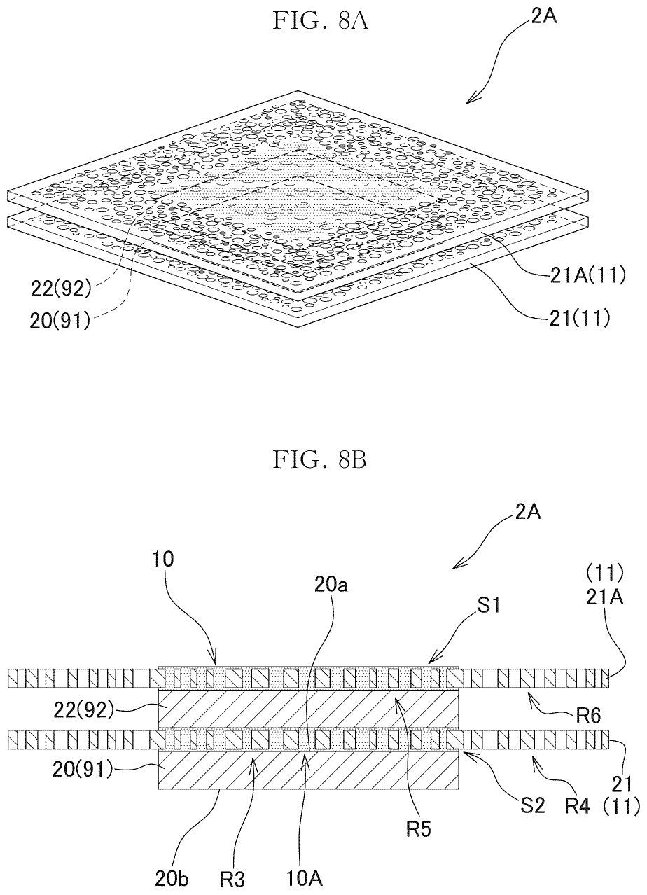

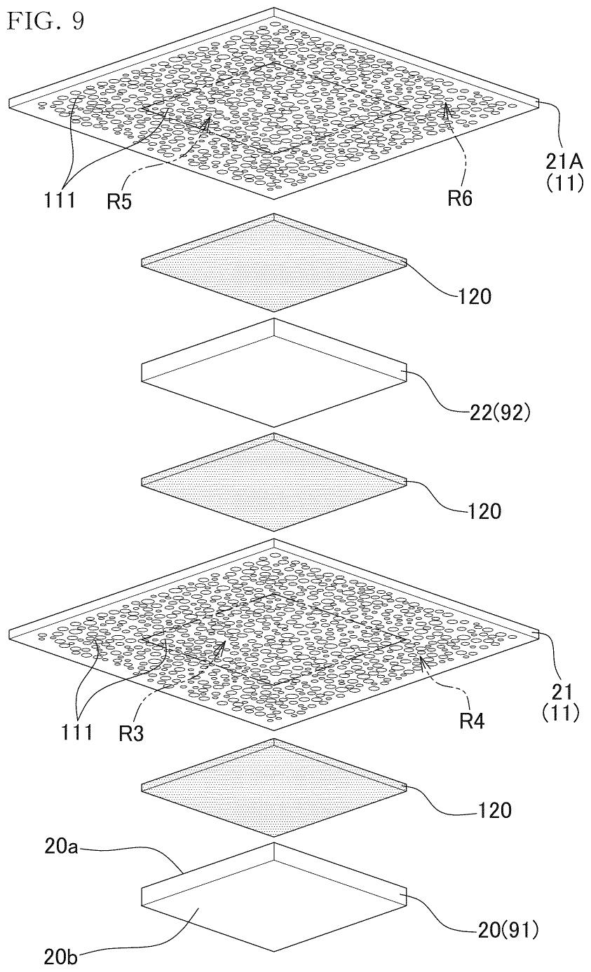

Next, an example of a heatsink including the heat conductive joining structure S2 will be described based on FIG. 8A, FIG. 8B, and FIG. 9.

A heatsink 2A in this example corresponds to an improvement of the heatsink described in Japanese Unexamined Patent Application Publication No. 2018-73869, similarly to the heatsink 2. The heat conductive joining structure S2 is used, so that the production can be performed more efficiently and accurately, and excellent joining strength and the heat conduction from the heat absorber to the cooling fin can be obtained.

Specifically, as shown in FIG. 8A and FIG. 8B, the heatsink 2A includes a metallic heat absorber 20 that has an abutting surface 20b abutting on an object to be cooled and receives the heat from the object to be cooled through the abutting surface, a metallic first plate-shaped fin 21 that has a plate surface with a partial region R3 that is joined to a surface 20a of the heat absorber 20 on the opposite side of the abutting surface 20b, a metallic coupling body 22 that is joined to a region of a plate surface of the first plate-shaped fin 21, on the opposite side of the plate surface, and corresponds to the partial region R3, and a metallic second plate-shaped fin 21A that has a plate surface with a partial region R5 that joins to a surface of the coupling body 22 on the opposite side of the surface joining to the first plate-shaped fin 21.

Moreover, at the partial region R3 of the plate-shaped fin 21, the heat absorber 20, the plate-shaped fin 21, and a joining layer 10A of the coupling body 22 are configured by the solid solidified body 12 including the filling portions 121 with which through-holes 111 at the region R3 are filled and the solder films 122 and 123 that are continuous with the filling portions 121 and spread on upper and lower plate surfaces of the plate-shaped fin 21, while the heat absorber 20 is adopted as one member 91 of the two members, the first plate-shaped fin 21 is adopted as the porous base plate 11, and the coupling body 22 is adopted as the other member 92 of the two members. The solder films 122 and 123 face and are in tight contact with the heat absorber 20 and the coupling body 22 respectively, so as to efficiently perform heat conduction with the heat absorber 20 and the coupling body 22, respectively. The coupling body 22 and the second plate-shaped fin 21A are joined by the heat conductive joining structure S1 including the same joining layer 10 as that in the example of the above-described heatsink 2.

A residual region R4 of the first plate-shaped fin 21 that projects at the periphery of the heat absorber 20 and the coupling body 22 and a residual region R6 of the second plate-shaped fin 21A that projects at the periphery of the coupling body 22 function as radiation fins that radiate heat to fluid passing through the through-holes 111, respectively. The heatsink 2A in this example exerts the above-described effects obtained by the heat conductive joining structures S1 and S2, i.e., an excellent tight contact property and heat conductibility, can mitigate the stress, and has excellent joining strength, as compared to a heatsink in which a plate end portion of the radiation fin is joined to a heat absorber sidewall as in the conventional heatsink.

In this example, only one coupling body 22 is provided and two radiation fins that are the plate-shaped fins 21 and 21A are arrayed in an axial direction perpendicular to the plate surface. However, it is allowable to adopt a heatsink in which two or more heat conductive joining structures S2 are consecutively provided in the axial direction to provide two or more coupling bodies 22, and three or more radiation fins are arrayed. According to the heat conductive joining structures S1 and S2 in the present invention, it is possible to accurately assemble a plurality of radiation fins parallel to each other in this way, to efficiently conduct the heat absorbed by the fins, and to efficiently radiate the heat from the fins.

As shown in FIG. 9, the heatsink 2 is configured in a manner that the solder plate 120, the plate-shaped fin 21, the solder plate 120, the coupling body 22, the solder plate 120, and the plate-shaped fin 21A are placed and stacked in order over a top surface of the heat absorber 20. The plate-shaped fins 21 and 21A are placed so that the regions R3 and R5 at the respective centers are put so as to correspond to the respective positions of the solder plates 120, and the residual regions R4 and R6 are positioned at the respective peripheries. Then, each solder plate 120 is melted by the heating with the heater 4, a heating furnace, or the like. Accordingly, solder in each solder plate 120 enters the through-holes 111 at the regions R3 and R5 close to the respective centers of the plate-shaped fins 21 and 21A, forms the solder films 122 and 123 on both surfaces of each fin, and is solidified.

The solders solidified in the through-holes 111 of each fin form the filling portions 121, respectively. In this way, the joining layer 10A (heat conductive joining structure S2) in which the plate-shaped fin 21 is in tight contact with the heat absorber 20 and the coupling body 22 and the joining layer 10 (heat conductive joining structure S1) in which the plate-shaped fin 21A is in tight contact with the coupling body 22 are formed. Other structures, materials, modifications, and the like are the same as those in the above heatsink 2, and thus descriptions thereof are omitted.

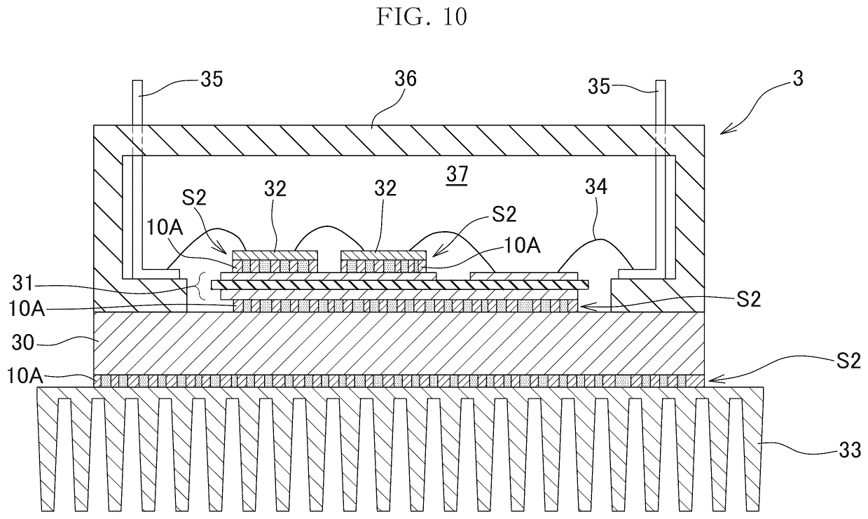

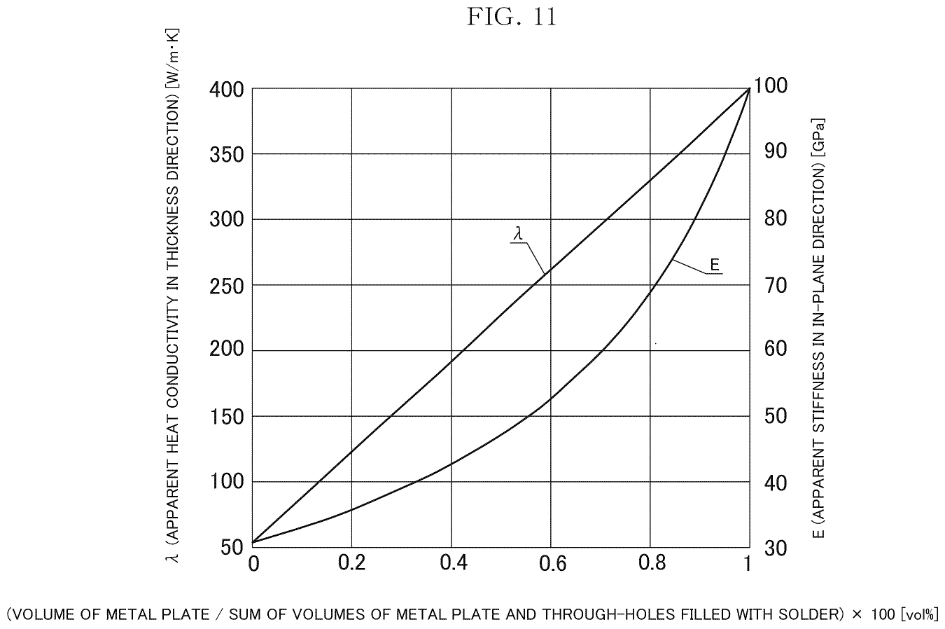

Next, an example of a semiconductor device including the heat conductive joining structure S2 will be described based on FIG. 10.

A semiconductor device 3 in this example includes a base plate 30, a circuit substrate 31 that is joined on the base plate 30, a semiconductor chip 32 that is joined on the circuit substrate 31, and a heatsink 33 that is disposed below the base plate 30. The heat conductive joining structure S2 including the above joining layer 10A is provided at each of an interval between the base plate 30 and the circuit substrate 31, an interval between the circuit substrate 31 and the semiconductor chip 32, and an interval between the base plate 30 and the heatsink 33. Reference numerals 34, 35, 36, and 37 respectively denotes a bonding wire, a terminal, a case, and a filler.

The semiconductor device 3 in which the heat conductive joining structure S2 in the present invention is used in this way has an excellent tight contact property and heat conductibility in the joining portions, mitigates the stress that is generated in the joining portions, and has such excellent durability of preventing the break or the peeling before it happens. Therefore, it is possible to achieve efficient heat radiation and stress mitigation, and to expect the downsizing and long life of the device. Further, because of having high stiffness and assembly accuracy, it is possible to stably and efficiently provide an excellent-quality device that has strength and accuracy in accordance with the design. The heat conductive joining structure S2 is used in each of the joining portions in this example, but may be employed in only some of the joining portions. Further, the structure of the semiconductor device is not limited to the illustrated structure at all, and needless to say, can be applied to various devices.

The embodiments of the present invention have been described above. The present invention is not limited to the embodiments at all, and naturally, can be carried out in various modes without departing from the spirit of the present invention.

### REFERENCE SIGNS LIST

S1, S2 heat conductive joining structure
2,2A heatsink
3 semiconductor device
4 heater
9 member
10,10A joining layer
11 porous base plate
12 solder solidified body
20 heat absorber
20a surface
20b abutting surface
21,21A plate-shaped fin
22 coupling body
30 base plate
31 circuit substrate
32 semiconductor chip
33 heatsink
91,92 member
111 through-hole
120 solder plate
121 filling portion
122, 123 solder film
R1 to R6 region

1. A heat conductive joining structure including a joining layer that is in tight contact with a certain member to perform heat conduction with the member,
the joining layer comprising:
a metallic porous base plate provided with a plurality of through-holes extending in a thickness direction and opening on both front and back plate surfaces of the porous base plate; and
a solder solidified body including filling portions with which the through-holes of the porous base plate are filled, and a solder film that is continuous with the filling portions and spreads on at least one of the plate surfaces, wherein
the solder film is in tight contact with and joins to the member which the solder film faces,

2. A heat conductive joining structure including a joining layer that is provided between two members to join the two members, and transfers heat from one of the two members to a remaining one of the two members,
the joining layer comprising:
a metallic porous base plate that is provided with a plurality of through-holes and is interposed between the two members, the plurality of through-holes extending in a thickness direction and opening on both front and back plate surfaces of the metallic porous base plate; and
a solder solidified body including filling portions with which the through-holes of the porous base plate are filled, and a solder film that is continuous with the filling portions and spreads on each of the plate surfaces, wherein
the solder film is in tight contact with and joins to a corresponding one in the two members which the solder film faces.

3. The heat conductive joining structure according to claim 1, wherein
a void ratio due to the through-holes of the porous base plate constituting the joining layer is 30 to 80 vol %.

4. A heat conductive joining method including providing a joining layer that is in tight contact with a certain member to perform heat conduction with the member,
the providing the joining layer comprising:
providing a metallic porous base plate provided with a plurality of through-holes extending in a thickness direction and opening on both front and back plate surfaces of the metallic porous base plate; and
filling the through-holes of the porous base plate with a solder material, forming a solder film that is continuous with filling portions and spreads on at least one of plate surfaces of the porous base plate, and performing solidification, thereby providing a solder solidified body wherein
the solder film is in tight contact with and joins to the member which the solder film faces.

5. A heat conductive joining method including providing a joining layer between two members to join the two members, the joining layer transferring heat from one of the two members to a remaining one of the two members,
the providing the joining layer comprising:
interposing a metallic porous base plate provided with a plurality of through-holes between the two members, the plurality of through-holes extending in a thickness direction and opening on both front and back plate surfaces of the metallic porous base plate; and
filling the through-holes of the porous base plate with a solder material, forming a solder film that is continuous with the filling portions and spreads on each of the plate surfaces, and performing solidification, thereby providing a solder solidified body, wherein
the solder film is in tight contact with and joins to a corresponding one of the two members, which the solder film faces.

6. The heat conductive joining method according to claim 4, comprising:
interposing the solder material between one or both of the front and back plate surfaces of the porous base plate and the member that faces at least one of the front and back plate surfaces; and
stacking and heating the member, the porous base plate, and the solder material, melting the solder material, filling the through-holes of the porous base plate with the solder material, forming a solder film that is continuous with the filling portions and spreads on each of the plate surfaces, and performing cooling solidification, thereby forming the solder solidified body.

7. The heat conductive joining method according to claim 6, wherein
the two members, the porous base plate, and the solder material are stacked in a vertical direction, and are heated to melt the solder material while the solder material is disposed on a top surface of the porous base plate;
the solder material falls and fills into the through-holes due to a self-weight of the solder material and a weight of a member above the solder material;
the solder material leaks from openings of the through-holes on a lower side thereof, spreads on a gap between the porous base plate and a member below the porous base plate, and forms the solder film on the plate surface of the porous base plate on a lower side; and
a residual solder material that has not fallen into the through-holes forms the solder film on the plate surface of the porous base plate on an upper side.

8. A heatsink including the heat conductive joining structure according to claim 1, the heatsink comprising:
a metallic heat absorber as the certain member, the heat absorber having an abutting surface that abuts on an object to be cooled, and transfer heat of the object to the heat absorber through the abutting surface; and
a metallic plate-shaped fin as the porous base plate, the metallic plate-shaped fin having a plate surface with a partial region that joins to a surface of the heat absorber on an opposite side of the abutting surface, wherein
the plate-shaped fin is provided with a plurality of through-holes opened on the plate surface;
the solder solidified body is provided at the partial region of the plate-shaped fin, the solder solidified body including the filling portions with which through-holes formed at the partial region are filled, and the solder film that is continuous with the filling portions and spreads on the plate surface, and the solder film is in tight contact with the heat absorber which the solder film faces to form the joining layer that performs heat conduction with the heat absorber; and
heat is radiated to an exterior through through-holes at a residual region of the plate-shaped fin, the residual region of the plate-shaped fin projecting at a periphery of the heat absorber.

9. A heatsink including the heat conductive joining structure according to claim 2, the heatsink comprising:
a metallic heat absorber as one member of the two members, the heat absorber having an abutting surface that abuts on an object to be cooled, and transfers heat of the object to be cooled to the heat absorber through the abutting surface;
a first metallic plate-shaped fin as the porous base plate, the first metallic plate-shaped fin having a plate surface with a partial region that joins to a surface of the heat absorber on an opposite side of the abutting surface;
a metallic coupling body as a remaining one of the two members, the metallic coupling body joining to a region of a plate surface of the first plate-shaped fin on an opposite side of the plate surface with the partial region, the region corresponding to the partial region; and
a second metallic plate-shaped fin having a plate surface with a partial region that joins to a surface of the coupling body on an opposite side of the surface joining to the first plate-shaped fin, wherein
each of the first plate-shaped fin and the second plate-shaped fin has a plate surface on which a plurality of through-holes open;
the solder solidified body is provided at the partial region of the first plate-shaped fin, the solder solidified body including the filling portions with which through-holes formed at the partial region are filled, and the solder film that is continuous with the filling portions and spreads on plate surface of the first plate-shaped fin, the solder film being in tight contact with the heat absorber which the solder film faces and the coupling body which the solder film faces, the joining layer is formed, the joining layer transferring heat from the heat absorber to the coupling body; and
heat is radiated to an exterior through through-holes at a residual region of the first plate-shaped fin and through-holes at a residual region of the second plate-shaped fin, the residual region of the first plate-shaped fin projecting at a periphery of the heat absorber and the coupling body, the residual region of the second plate-shaped fin projecting at a periphery of the coupling body.

10. A semiconductor device comprising:
a base plate;
a circuit substrate that joins on the base plate; and
a semiconductor chip that is joined on the circuit substrate, wherein the heat conductive joining structure according to claim 2 including the joining layer is included in at least one of an interval between two members including the base plate and the circuit substrate and an interval between two members including the circuit substrate and the semiconductor chip.

11. A semiconductor device comprising:
a heatsink provided below a bottom surface of a base plate on which a circuit substrate and a semiconductor chip are laminated, and
the heat conductive joining structure according to claim 2 including the joining layer between two members including the base plate and the heatsink.
